(19) United States
(12) Patent Application Publication
(10) Pub. No.: US 2021/0091222 A1
(43) Pub. Date: Mar. 25, 2021

(54) FIN STRUCTURES OF FINFET DEVICES

(71) Applicant: GLOBALFOUNDRIES U.S. INC., Santa Clara, CA (US)

(72) Inventors: TAO CHU, Portland, OR (US); BINGWU LIU, Clifton Park, NY (US); ANTON VADIMOVICH TOKRANOV, Cohoes, NY (US); WEI MA, Clifton Park, NY (US); EDMUND KENNETH BANGHART, Pittsford, NY (US); GEORGE ROBERT MULFINGER, Gansevoort, NY (US); TYLER JAMES SHERWOOD, Fonda, NY (US)

(21) Appl. No.: 16/579,848

(22) Filed: Sep. 24, 2019

(51) Int. Cl. H01L 29/78; H01L 29/10; H01L 29/66; H01L 21/762; H01L 21/3065

(52) U.S. Cl. CPC H01L 29/7851; H01L 29/1037; H01L 21/3065; H01L 21/76224; H01L 29/66795

(57) ABSTRACT

A FinFET device is provided, which includes a semiconductor substrate, a fin structure and a dielectric material. The fin structure is extending from the semiconductor substrate, the fin structure having an upper fin section, a middle fin section and a lower fin section. The dielectric material is over the semiconductor substrate embedding a first portion of the lower fin section. The dielectric material forms shallow trench isolation regions of the FinFET device.

### FIELD OF THE INVENTION

The disclosed subject matter relates generally to semiconductor devices, and more particularly to fin structures of fin-type field effect transistor (FinFET) devices and methods of forming the same.

### BACKGROUND

A fin-type field effect transistor (FinFET) device is a type of non-planar multi-gate transistor device having raised “fin” channels over a semiconductor substrate. The FinFET devices have significantly higher switching speed and higher current density than the mainstream complementary metal-oxide-semiconductor (CMOS) devices. While the FinFET devices show improved leakage current performance over the CMOS devices, leakage current persists due to short channel effects (SCEs) and gate-induced drain leakage (GIDL).

Leakage current due to SCEs and GIDL decreases with narrower fins. However, despite the advantages of narrower fins, the drive current for the FinFET devices may be adversely affected as the fins get thinner, and there may have significant challenges in the fabrication process as well.

For the reasons described above, FinFET devices having fin structures to realize high drive current and low leakage current and methods of forming the same are presented.

### SUMMARY

To achieve the foregoing and other aspects of the present disclosure, FinFET devices having fin structures to realize high drive current and low leakage current and methods of forming the same are presented.

According to an aspect of the present disclosure, a FinFET device is provided, which includes a semiconductor substrate, a fin structure and a dielectric material. The fin structure is extending from the semiconductor substrate, the fin structure having an upper fin section, a middle fin section and a lower fin section. The dielectric material is over the semiconductor substrate embedding a first portion of the lower fin section. The dielectric material forms shallow trench isolation regions of the FinFET device.

According to another aspect of the present disclosure, a method of fabricating a FinFET device is provided, which includes providing a semiconductor substrate and forming an upper fin section from the semiconductor substrate. A middle fin portion is subsequently formed from the semiconductor substrate. A lower fin section is thereafter formed from the semiconductor substrate. The upper fin section, the middle fin section and the lower fin sections form a fin structure of the FinFET device. Shallow trench isolation regions are formed adjacent to and covering a portion of the lower fin section.

According to yet another aspect of the present disclosure, a method of fabricating a FinFET device is provided, which includes providing a semiconductor substrate and forming an upper fin section having a first width from the semiconductor substrate. A middle fin section having a second width is subsequently formed from the semiconductor substrate. The second width is narrower than the first width. A lower fin section having a third width is thereafter formed from the semiconductor substrate. The third width is wider than the second width. A dielectric material is deposited to form shallow trench isolation covering a portion of the lower fin section.

### BRIEF DESCRIPTION OF THE DRAWINGS

The embodiments of the present disclosure will be better understood from a reading of the following detailed description, taken in conjunction with the accompanying drawings:

FIGS. 1A-1H are cross-sectional views of a partially processed FinFET device, illustrating a method of forming fin structures having concave sidewalls, according to an embodiment of the disclosure.

For simplicity and clarity of illustration, the drawings illustrate the general manner of construction, and certain descriptions and details of well-known features and techniques may be omitted to avoid unnecessarily obscuring the discussion of the described embodiments of the disclosure. Additionally, elements in the drawings are not necessarily drawn to scale. For example, the dimensions of some of the elements in the drawings may be exaggerated relative to other elements to help improve understanding of embodiments of the disclosure. The same reference numerals in different drawings denote the same elements, while similar reference numerals may, but do not necessarily, denote similar elements.

### DETAILED DESCRIPTION

Various embodiments of the disclosure are described below. The embodiments disclosed herein are exemplary and not intended to be exhaustive or limiting to the disclosure.

The present disclosure relates to fin structures of FinFET devices, the fin structures having laterally opposite concave sidewalls to realize high drive current and low leakage current and methods of forming the same. The concave sidewalls form a narrower width at a middle section of the fin structure that advantageously reduces leakage current, while wider widths at upper sections are ideal for achieving improved drive current for the FinFET devices. It is also preferable to have wider widths at lower sections of the fin structures to improve yield and reduce defects by facilitating subsequent nucleation of epitaxial material. The epitaxial material forms source and drain regions of the FinFET devices. The fin structures of the FinFET devices may be formed on bulk silicon substrate, semiconductor-on-insulator (SOI) substrate or other suitable semiconductor substrates.

Embodiments of the disclosure are now described in detail with accompanying drawings. It is noted that like and corresponding elements are referred to by the use of the same reference numerals.

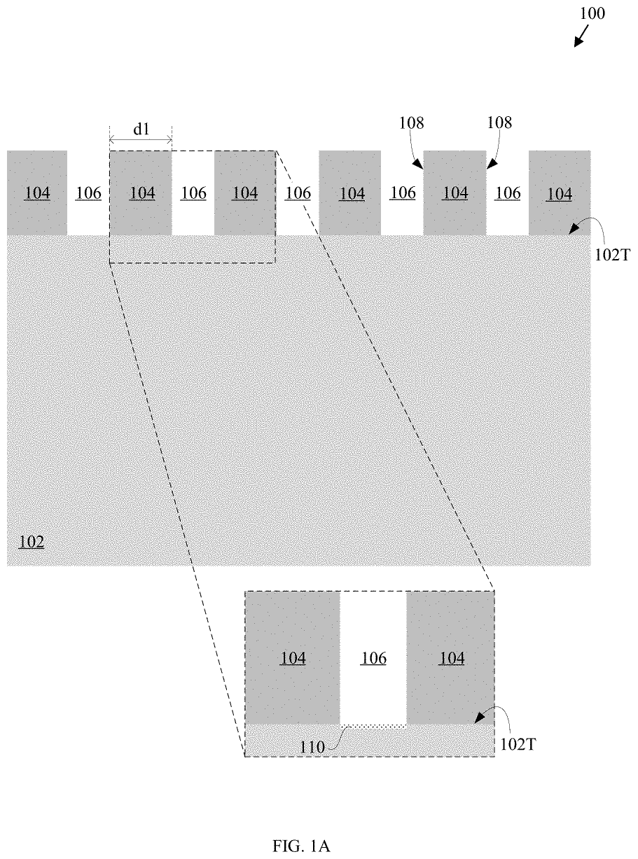

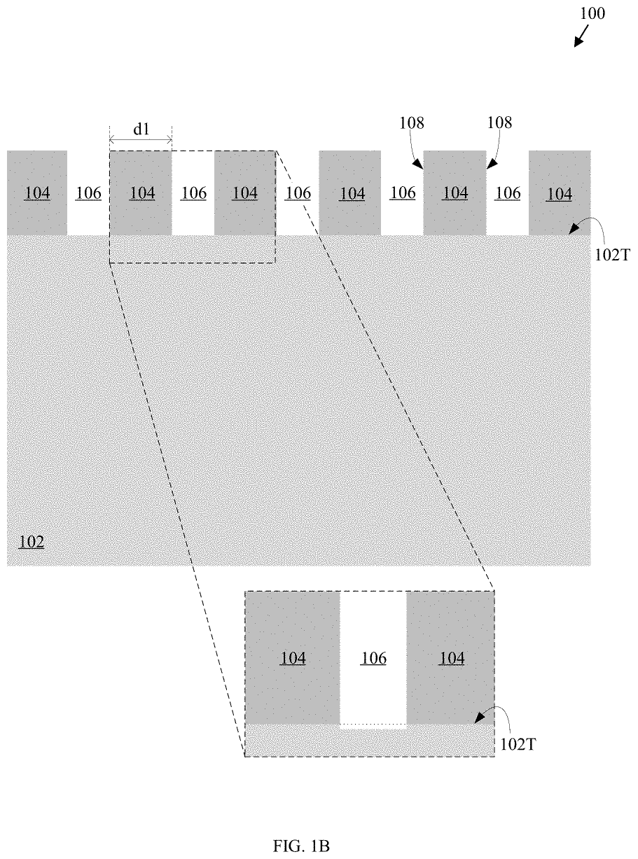

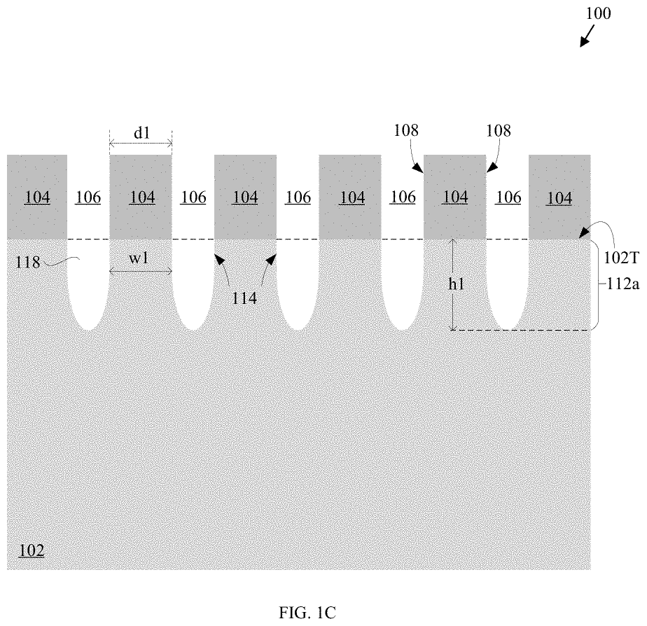

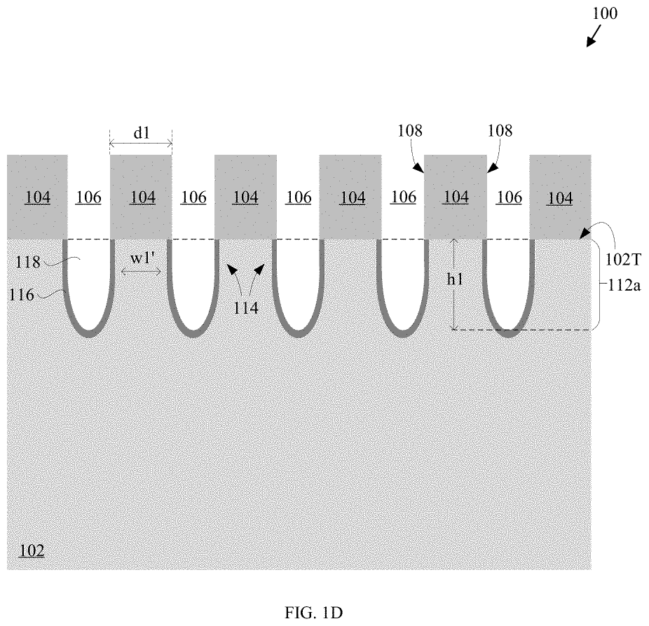

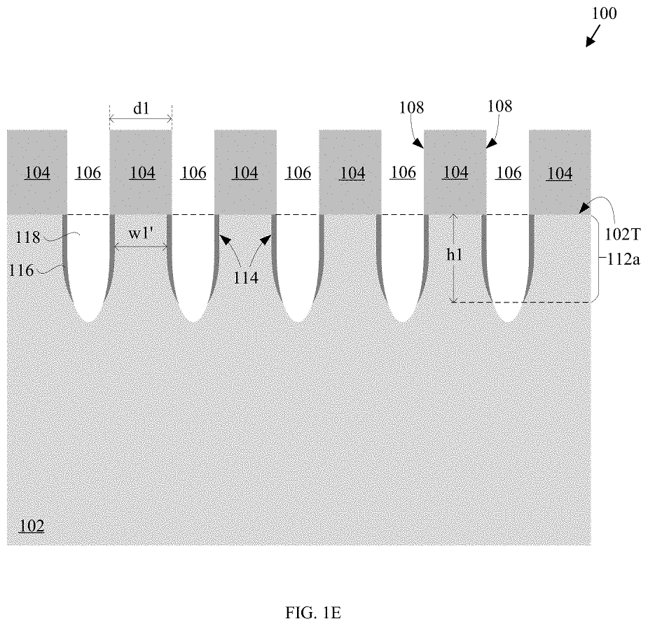

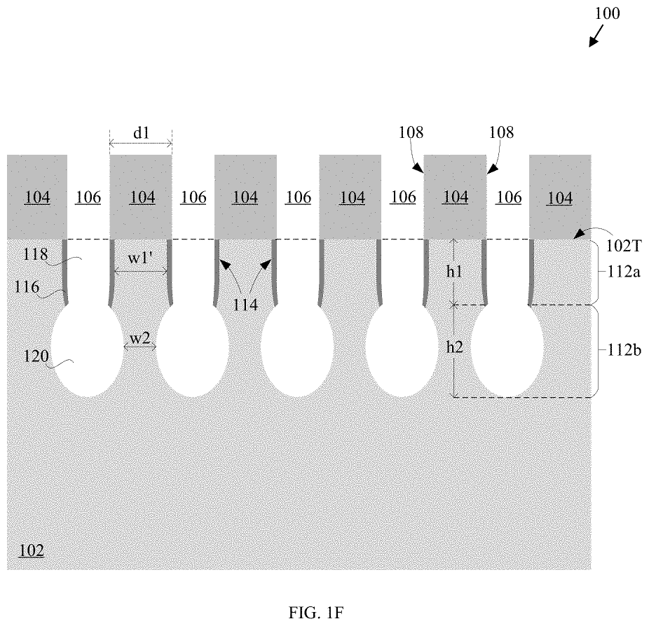

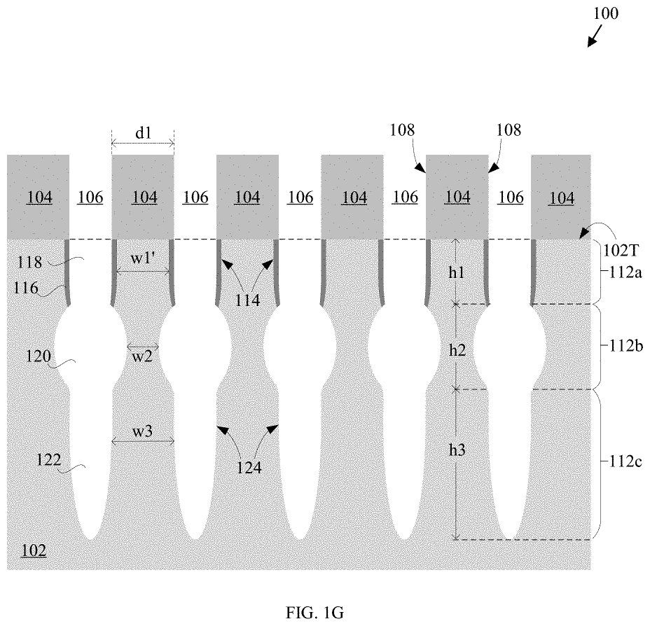

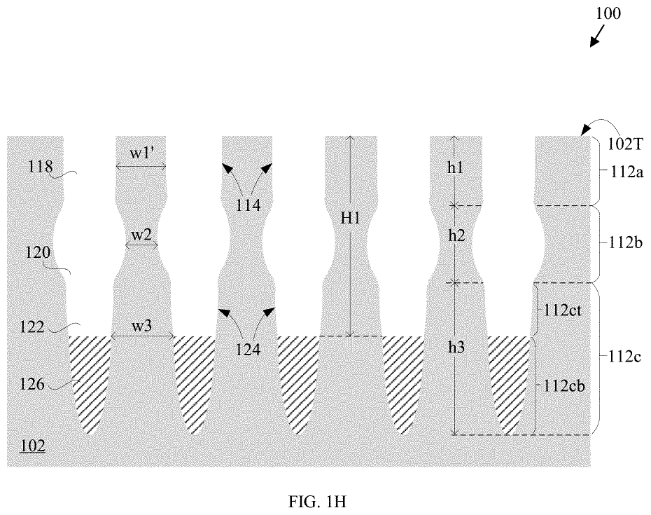

FIGS. 1A-1H are cross-sectional views of a partially processed FinFET device 100, illustrating a method of forming fin structures having concave sidewalls, according to embodiments of the disclosure, which are described in detail below.

As illustrated in FIG. 1A, the FinFET device 100 includes a semiconductor substrate 102. The semiconductor substrate 102 has a top surface 102T. The semiconductor substrate 102 may be doped or undoped and may include of any suitable semiconductor material, such as silicon, silicon germanium, silicon carbide, other II-VI or III-V semiconductor compounds and the like. The semiconductor substrate 102 may also include other types of semiconductor substrates such as silicon-on-insulator (SOI), multi-layered substrates or gradient substrates. In this embodiment of the disclosure, the semiconductor substrate is preferably silicon.

A patterning layer (not shown) is deposited over the semiconductor substrate 102 using a suitable deposition process, such as a chemical vapor deposition (CVD) process or a spin-coating process. A plurality of fin-defining masking portions 104 is formed over the semiconductor substrate 102 by forming openings 106 in the patterning layer using a material removing process. Areas of the semiconductor substrate 102 are exposed in the openings 106. An oxide layer 110 may be formed in the exposed areas of the semiconductor substrate 102 as a result of a natural oxidation process.

The masking portions 104 are preferably formed of a material that is capable of protecting the top surface of the semiconductor substrate 102T from subsequent processing steps. The masking portions 104 may include any suitable patterning materials having any suitable thickness; e.g., a polysilicon layer, an oxide layer, a nitride layer or a combination thereof. In some embodiments of the disclosure, the masking portions 104 may include a stack of silicon nitride and silicon oxide. In other embodiments of the disclosure, the masking portions 104 may include an organic planarization layer (OPL) or a photoresist layer

The plurality of fin-defining masking portions 104 laterally extends in a lengthwise direction over the semiconductor substrate 102. Each of the fin-defining masking portion 104 has a pair of substantially vertical laterally opposite sidewalls 108 that are separated along a widthwise direction, perpendicular to the lengthwise direction. As used herein, the term “lengthwise direction” is a direction along which an object extends the most. In one embodiment of the disclosure, each fin-defining masking portion 104 has a substantially uniform width dl.

FIG. 1B illustrates the FinFET device 100 after removing the oxide layer 110 from the openings 106, according to an embodiment of the disclosure. Using a suitable material removing process, the oxide layer 110 formed in the exposed areas of the semiconductor substrate 102 may be removed. The removed oxide layer 110 is demarcated by a dotted line. The material removing process exposes “clean” areas of the semiconductor substrate 102 in the openings 106. The undesirable presence of the oxide layer 110 may hinder the subsequent processing steps of forming fin structures 112 in the semiconductor substrate 102.

The material removing process may be performed in a reaction chamber, including plasma of a reactive gas mixture created by applying thereto a radio frequency (RF) power. The reaction chamber may be preferably maintained at a suitable operational pressure to maintain the plasma in the reaction chamber. In this embodiment of the disclosure, the oxide removing process may be performed by an exemplarily etch chemistry including tetrafluoromethane (CF₄) and argon (Ar). A combination of CF₄ and Ar reactive gases may flow into a reaction chamber at a flow rate of 100 sccm and 200 sccm, respectively. The reaction chamber may be maintained at an operational pressure of 10 mTorr and at a chuck temperature of 88° C. A radio frequency (RF) power of 400 W, coupled with a RF bias of 150 W may be continuously applied for processing duration of 7.5 seconds to effectively remove the undesirable oxide layer 110 from the exposed areas of the semiconductor substrate 102. Various adjustments may be made to the etch chemistry, the operational pressure, the RF power and the processing duration as needed.

FIG. 1C illustrates the FinFET device 100 after forming a plurality of upper fin sections 112a, which starts the formation of the fin structures 112, according to an embodiment of the disclosure. Using a suitable material removing process and the fin-defining masking portions 104 as a masking feature, a plurality of cavities 118 may be formed by removing a first portion of the semiconductor substrate 102 through each of the openings 106. The plurality of upper fin sections 112a is formed from the semiconductor substrate 102; each of the upper fin sections 112a is separated by an adjacent pair of cavities 118. The formed plurality of upper fin sections 112a is laterally extending in the same lengthwise direction as the fin-defining masking portions 104. Each of the upper fin sections 112a has a pair of substantially vertical laterally opposite sidewalls 114 that are separated along the widthwise direction, perpendicular to the lengthwise direction.

The material removing process may be a time-controlled process and may continue until the upper fin sections 112a reach a predetermined upper fin height h1. In one embodiment of the disclosure, the upper fin height h1 is preferably ranging from about 5 nm to about 30 nm. The upper fin sections 112a have an upper fin width w1 that may be substantially similar to the width dl of the fin-defining masking portions 104, the upper fin width w1 ranging from about 10 nm to about 35 nm. In another embodiment of the disclosure, the material removing process may be an anisotropic etching process, such as a reactive ion etching (RIE) process.

In this embodiment of the disclosure, the material removing process may be performed by an exemplarily etch chemistry including nitrogen (N₂), oxygen (O₂) and chlorine (Cl₂). A combination of N₂, O₂ and Cl₂ gases may flow into a reaction chamber at a flow rate of 50 sccm, 2 sccm and 150 sccm, respectively. The reaction chamber may be maintained at an operational pressure of 10 mTorr and at a chuck temperature of 88° C. A continuous RF power of 800 W, coupled with a RF bias of 400 W pulsed at a frequency of 50 Hz using direct current (DC) at 20% bias duty cycle, may be applied for a processing duration of 24 seconds to form the plurality of upper fin sections 112a in the semiconductor substrate 102. As used herein, the duty cycle is defined as the ratio of pulse on time (or pulse width) to pulse off time. Various adjustments may be made to the etch chemistry, the operational pressure, the RF power and the processing duration as needed.

The applied RF bias may be preferably increased to 400 W to increase the etching rate of the semiconductor substrate 102 and to obtain a more vertical sidewall profile on the upper fin sections 112a. The applied RF bias may be pulsed to beneficially modify the overall characteristics of the etching process, such as to obtain increased etch selectivity between the semiconductor substrate 102 and the fin-defining masking portions 104. The increased RF bias may increase the vertical directionality of the plasma of reactive gases, thereby effectively controlling the sidewall profiles of the upper fin sections 112a. The processing duration may also be adjusted accordingly to control the upper fin height h1; a longer processing duration will result in greater upper fin height h1.

FIG. 1D illustrates the FinFET device 100 after forming an oxide layer 116 in outer portions of the upper fin sections 112a, according to an embodiment of the disclosure. Using a suitable oxidation process, the plurality of upper fin sections 112a is exposed to an oxygen-containing environment and the oxide layer 116 having a predetermined thickness is formed in the outer portions of the upper fin sections 112a. Consequent to forming the oxide layer 116, the upper fin sections 112a have a reduced upper fin width w1′ narrower than the upper fin width w1. The thickness of the oxide layer 116 may be adjusted to control the upper fin width w1′. In one embodiment of the disclosure, the oxide layer 116 may be a silicon dioxide layer. In another embodiment of the disclosure, the upper fin width w1′ is preferably in the range of about 5 nm to about 35 nm.

In this embodiment of the disclosure, the oxidation process may be performed by an exemplarily oxidizing chemistry including Ar and O₂. A combination of Ar and O₂ gases may flow into a reaction chamber at a flow rate of 200 sccm and 100 sccm, respectively. The reaction chamber may be maintained at an operational pressure of 20 mTorr and at a chuck temperature of 88° C. A RF power of 1300 W, coupled with a 0 W RF bias, may be continuously applied for processing duration of 45 seconds to form the oxide layer 116 in the outer portions of the upper fin sections 112a. Various adjustments may be made to the oxidizing chemistry, the operational pressure, the RF power and the processing duration as needed.

The applied RF power may be preferably increased to 1300 W, and the operational pressure may be increased to 20 mTorr, to increase the oxidation rate of the outer portions of the upper fin sections 112a. The high RF power advantageously maximizes the number of oxygen radicals in the oxygen-containing environment in order to form a complete oxide layer 116 in the outer portions of the upper fin sections 112a. The processing duration may also be adjusted accordingly to a predetermined upper fin width w1 ‘; a longer processing duration will result in a thicker oxide layer 116 and a narrower upper fin width w1’ of the upper fin sections 112a.

FIG. 1E illustrates the FinFET device 100 after removing portions of the oxide layer 116 at the bottom of the cavities 118, according to an embodiment of the disclosure. Using a suitable material removing process, the portions of the oxide layer 116 at the bottom of the cavities 118 may be removed without substantially removing portions of the oxide layer 116 in the sidewalls 114 of the upper fin sections 112a. The material removing process advantageously exposes areas of the semiconductor substrate 102 at the bottom of the cavities 118 for subsequent effective extension of the cavities 118 into the semiconductor substrate 102.

In this embodiment of the disclosure, the material removing process may be performed by an exemplarily etch chemistry including helium (He), CF₄ and O₂. A combination of He, CF₄ and O₂ gases may flow into a reaction chamber at a flow rate of 200 sccm, 80 sccm and 8 sccm, respectively. The reaction chamber may be maintained at an operational pressure of 30 mTorr and at a chuck temperature of 88° C. A RF power of 2000 W, coupled with 0 W RF bias, may be continuously applied for processing duration of 11.5 seconds to remove the portions of the oxide layer 116 at the bottom of the cavities 118. Various adjustments may be made to the etch chemistry, the operational pressure, the RF power and the processing duration as needed.

FIG. 1F illustrates the FinFET device 100 after further extending the cavities 118 into the semiconductor substrate 102, according to an embodiment of the disclosure. Using a suitable material removing process, an additional portion of the semiconductor substrate 102 may be isotropically removed through each of the openings 106 to form “ball-shaped” cavities 120. The portions of the oxide layer 116 on the sidewalls 114 of the upper fin sections 112a form a barrier layer, protecting the sidewalls 114 from the material removing process.

In some embodiments of the disclosure, it is preferable to form the upper fin height h1 beyond the predetermined upper fin height. In those embodiments, the upper fin height h1 is preferably ranging from about 20 nm to 120 nm. Forming the cavities 120 may consequently remove lower portions of the upper fin sections 112a, thereby reducing the upper fin height h1.

A plurality of middle fin sections 112b is formed below the upper fin sections 112a and each of the middle fin section 112b may be separated by an adjacent pair of cavities 120. The middle fin section 112b has a middle fin height h2 and a middle fin width w2 at a narrowest portion of the middle fin section 112b. The middle fin width w2 is narrower than the upper fin width w1′. In one embodiment of the disclosure, the material removing process may be an isotropic etching process, such as an RIE process.

The material removing process may be a time-controlled process and may continue until the middle fin sections 112b reach a predetermined middle fin width w2. In one embodiment, the middle fin width w2 is at least 0.5 nm narrower than the upper fin width w1′. In another embodiment of the disclosure, the middle fin sections 112b have a preferable middle fin width w2 ranging from about 4 nm to about 30 nm. In yet another embodiment of the disclosure, the middle fin sections 112b have a preferable middle fin height h2 ranging from about 5 nm to about 30 nm.

In one embodiment of the disclosure, the material removing process may be performed by an exemplarily etch chemistry including N₂, Cl₂ and nitrogen trifluoride (NF₃). A combination of N₂, Cl₂ and NH₃ gases may flow into a reaction chamber at a flow rate of 50 sccm, 50 sccm, and 20 sccm, respectively. The reaction chamber may be maintained at an operational pressure of 10 mTorr and at a chuck temperature of 88° C. A RF power of 800 W, coupled with 0 W RF bias, may be continuously applied for a processing duration of 30 seconds to form the middle fin sections 112b. Various adjustments may be made to the etch chemistry, the operational pressure, the RF power and the processing duration as needed.

The applied RF power may be preferably decreased to 800 W and the operational pressure may be decreased to 10 mTorr to enable a highly isotropic etching process to form the “ball-shaped” cavities 120. The “ball-shape” cavities 120 consequently affect the middle fin width w2, i.e., the bigger the “ball-shaped” cavities 120, the narrower the middle fin width w2.

FIG. 1G illustrates the FinFET device 100 after forming lower fin sections 112c from the semiconductor substrate 102, according to an embodiment of the disclosure. Using a suitable material removing process, a further portion of the semiconductor substrate 102 may be anisotropically removed through each of the openings 106 to form the lower fin sections 112c under the middle fin sections 112b. Each of the lower fin sections 112c may have substantially vertical sidewalls 124 and may be separated by an adjacent pair of cavities 122. Each of the lower fin sections 112c has a lower fin height h3 and a lower fin width w3. The lower fin width w3 may be preferably wider than the upper fin width w1′ and the middle fin width w2. In one embodiment of the disclosure, the lower fin width w3 is at least 0.5 nm wider than the middle fin width w2. In another embodiment of the disclosure, the middle fin width w2 is at least 7% narrower than the upper fin width w1′ or the lower fin width w3. In yet another embodiment of the disclosure, the material removing process may be an anisotropic etching process, such as an RIE process.

The material removing process may be a time-controlled process and may continue until the lower fin sections 112c reach a predetermined lower fin height h3. In one embodiment of the disclosure, the lower fin height h3 is preferably ranging from about 55 nm to about 130 nm. In another embodiment of the disclosure, the lower fin width w3 is preferably ranging from about 5 nm to about 30 nm.

In this embodiment of the disclosure, the material removing process may be performed by an exemplarily etch chemistry including N₂, O₂, Cl₂ and hydrogen bromide (HBr). A combination of N₂, O₂, Cl₂ and HBr gases may flow into a reaction chamber at a flow rate of 50 sccm, 3 sccm, 150 sccm and 15 sccm, respectively. The reaction chamber may be maintained at an operational pressure of 10 mTorr and at a chuck temperature of 88° C. A continuous RF power of 800 W, coupled with a RF bias of 500 W pulsed at a frequency of 50 Hz using DC at 20% bias duty cycle may be applied for a processing duration of 22 seconds to form the lower fin sections 112c. Various adjustments may be made to the etch chemistry, the operational pressure, the RF power and processing duration as needed.

FIG. 1H illustrates the FinFET device 100 after depositing a dielectric material 126 between the fin structures 112, according to an embodiment of the disclosure. The dielectric material 126 may be deposited using known semiconductor fabrication processes, including the following exemplary process. The dielectric material 126 may be deposited to completely fill the cavities 118, 120 and 122 and completely cover the fin-defining masking portions 104 (not shown), using a suitable deposition process such as a CVD process. The dielectric material 126 may be planarized to a level that is substantially coplanar with a top surface of the fin-defining masking portions 104 (not shown).

The dielectric material 126 may be subsequently recessed using a one or a multi-step material removing process. In one embodiment of the disclosure, the dielectric material 126 may be recessed using an isotropic etching process to a predetermined level. In another embodiment of the disclosure, the dielectric material 126 may be recessed using an anisotropic etching process, followed by an isotropic etching process to a predetermined level. The isotropic etching process advantageously removes potential dielectric material residue on sidewalls of the fin structures.

The dielectric material 126 is recessed to a level to expose a desired fin height H1. The desired fin height H1 may vary according to the specific designs of the FinFET devices. The exposed sections of the fin structures 112 form active regions that may function as channels for current flow for the FinFET device 100. A lower first portion of the lower fin section 112cb remains embedded in the dielectric material 124 and an upper second portion of the lower fin section 112ct is exposed. The dielectric material 126 may preferably be a dielectric material suitable to electrically isolate the adjacent fin structures 112, e.g., silicon dioxide or tetraethylorthosilicate (TEOS). In some embodiments of the disclosure, the recessed dielectric material 126 forms shallow trench isolation (STI) regions of the FinFET device 100.

In one embodiment of the disclosure, the lower first portion of the lower fin section 112cb may be preferably having a height ranging from about 50 nm to about 100 nm. In another embodiment of the disclosure, the upper second portion of the lower fin section 112cb may be preferably having a height ranging from about 5 nm to about 30 nm. In yet another embodiment of the disclosure, the fin height H1 may be preferably ranging from about 15 nm to about 80 nm. The fin-defining masking portions 104 (not shown) and the oxide material 116 (not shown) may be subsequently removed by employing suitable material removing process, such as a dry plasma ashing process, a selective wet etching process, a combination thereof or other suitable material removing processes.

In the above detailed description, methods of forming fin structures having concave sidewalls are presented. A plurality of fin structures is formed from a semiconductor substrate in several processing steps, including anisotropically removing a first portion of the semiconductor substrate to form substantially vertical upper fin sections, further isotropically removing a second portion of the semiconductor substrate to form middle fin sections having concave sidewalls, and yet further isotropically removing a third portion of the semiconductor substrate to form lower fin sections. The middle fin section has a middle fin width narrower than the upper and lower fin sections. The formation of the fin structures may take place in a single reaction chamber, using a single recipe including different processing steps.

The position of the middle fin sections may be controlled by adjusting the process parameters for forming the upper fin sections. For example, the upper fin sections may be formed deeper into the semiconductor substrate to form the middle fin sections at lower sections of the fin structures. Forming the middle fin section around a location of the fin structure having a highest leakage current advantageously reduces the leakage current at that location. The middle fin width may also be controlled by adjusting the process parameters for forming the middle fin sections. By adjusting the isotropic property of the material removing process, the middle fin width can be controlled. The wider widths at the upper fin sections retain a desirable high drive current for the FinFET devices.

An oxidation process may be performed after forming the upper fin sections, to form an oxide layer at outer portions of the upper fin sections. The oxidation process advantageously controls widths of the upper fin sections, such that the thicker the formed oxide layer, the narrower the width of the upper fin sections.

A dielectric material may be deposited between the fin structures to form shallow trench isolation regions to electrically isolate the adjacent fin structures. A first portion of the lower fin section may be embedded in the dielectric material and a second portion of the lower fin section may be exposed above the dielectric material. The upper fin sections, the middle fin sections and the second portions of the lower fin sections form active regions of the FinFET device. Active regions are regions that may function as channels for current flow for the FinFET device.

The terms “top”, “bottom”, “over”, “under”, and the like in the description and in the claims, if any, are used for descriptive purposes and not necessarily for describing permanent relative positions. It is to be understood that the terms so used are interchangeable under appropriate circumstances such that the embodiments of the device described herein are, for example, capable of operation in other orientations than those illustrated or otherwise described herein.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in one embodiment” herein do not necessarily all refer to the same embodiment.

In addition, unless otherwise indicated, all numbers expressing quantities, ratios, and numerical properties of materials, reaction conditions, and so forth used in the specification and claims are to be understood as being modified in all instances by the term “about”.

While several exemplary embodiments have been presented in the above detailed description of the device, it should be appreciated that a number of variations exist. It should further be appreciated that the embodiments are only examples, and are not intended to limit the scope, applicability, dimensions, or configuration of the device in any way. Rather, the above detailed description will provide those skilled in the art with a convenient road map for implementing an exemplary embodiment of the device, it being understood that various changes may be made in the function and arrangement of elements and method of fabrication described in an exemplary embodiment without departing from the scope of this disclosure as set forth in the appended claims.

1. A FinFET device comprising:
a semiconductor substrate; and
a fin structure extending from the semiconductor substrate, wherein the fin structure has an upper fin portion and a lower fin portion, the lower fin portion is embedded in a dielectric material over the semiconductor substrate and the upper fin portion vertically extends from the lower fin portion above the dielectric material and comprises curved concave side surfaces spaced apart from the dielectric material and
wherein the dielectric material forms shallow trench isolation regions of the FinFET device.

2. The FinFET device of claim 1, wherein the upper fin portion has a first width where the curved concave side surfaces are laterally closest and a second width at an intersection with an upper surface of the dielectric material and the first width is narrower than the second width.

3. The FinFET device of claim 2, wherein the first width is at least 7% narrower than the second width.

4. (canceled)

5. The FinFET device of claim 1, wherein the upper fin portion is an active region for the FinFET device.

6. (canceled)

7. The FinFET device of claim 2, wherein the first width is at least 0.5 nm narrower than the second width.

8. The FinFET device of claim 2, wherein the first width ranges from 4 nm to 30 nm.

9. The FinFET device claim 1, wherein the curved concave side surfaces have a height ranging from 5 nm to 30 nm.

10. (canceled)

11. The FinFET device of claim 1, wherein the lower fin portion has a height ranging from 50 nm to 100 nm.

12. The FinFET device of claim 1, wherein the curved concave side surfaces are 5 nm to 30 nm above the dielectric material.

13. A method of fabricating a FinFET device comprising:
providing a semiconductor substrate;
forming an upper fin portion from the semiconductor substrate, wherein the upper fin portion comprises curved concave side surfaces;
forming a lower fin portion from the semiconductor substrate, wherein the upper and the lower fin portions together form a fin structure of the FinFET device; and
forming shallow trench isolation regions adjacent to and covering the lower fin portion, wherein the curved concave side surfaces are spaced apart therefrom.

14. The method of claim 13, wherein forming the curved concave side surfaces comprises an isotropic etching process.

15. The method of claim 13, wherein forming the lower fin portion comprises an anisotropic etching process.

16. The method of claim 13, wherein forming the shallow trench isolation regions further comprises:
depositing a dielectric material over the semiconductor substrate and covering the fin structure; and
recessing the dielectric material to form the shallow trench isolation regions, exposing the upper fin portion.

17. A method of fabricating a FinFET device comprising:
providing a semiconductor substrate;
forming an upper fin portion from the semiconductor substrate, wherein the upper fin portion comprises curved concave side surfaces having a first width where the curved concave side surfaces are laterally closest;
forming a lower fin portion from the semiconductor substrate; and
depositing a dielectric material to form shallow trench isolation regions covering the lower fin portion, wherein the lower fin portion has a second width at an intersection with an upper surface of the dielectric material and the curved concave side surfaces are spaced apart from the dielectric material.

18. The method of claim 17, wherein the second width is wider than the first width.

19. The method of claim 17, wherein the curved concave side surfaces are formed by isotropically removing material from the semi conductor substrate.

20. (canceled)
